(19) United States
(12) Patent Application Publication
(10) Pub. No.: US 2025/0169015 A1
(43) Pub. Date: May 22, 2025

(54) PORTABLE POWER SUPPLY

(71) Applicant: JVCKENWOOD CORPORATION, Yokohama-shi (JP)

(72) Inventors: Koji OKAWA, Yokohama-shi (JP); Shinichi SAKANO, Yokohama-shi (JP); Takayuki UCHIDA, Yokohama-shi (JP); Yuji IIDA, Yokohama-shi (JP)

(21) Appl. No.: 19/029,967

(22) Filed: Jan. 17, 2025

Related U.S. Application Data
(63) Continuation of application No. PCT/JP2023/024649, filed on Jul. 3, 2023.

(30) Foreign Application Priority Data
Aug. 23, 2022 (JP) 2022-132348

(51) Int. Cl. H05K 5/13; H05K 5/00; H05K 5/02; H05K 5/03

(52) U.S. Cl. CPC H05K 5/13; H05K 5/0086; H05K 5/023; H05K 5/0234; H05K 5/0247; H05K 5/03

(57) ABSTRACT

A portable power supply includes a secondary battery and a housing. The housing includes a lower housing that accommodates and supports the secondary battery and has a box shape with an open upper surface, and a lid housing that is arranged to cover the lower housing from above. The housing includes handle parts on opposing edge parts of an upper edge part thereof so as to be portable by hand. Each of the handle parts includes a base part made from a metal, as a core material. The lid housing, the lower housing, and the base part of each of the handle parts are held through screwing of a male screw bolt and a female screw bolt which are inserted in the housing in a vertical direction of the housing.

### CROSS-REFERENCE TO RELATED APPLICATIONS

The present application is a continuation of International Application No. PCT/JP2023/024649 filed on Jul. 3, 2023, and based upon and claims the benefit of priority from Japanese Patent Application No. 2022-132348 filed on Aug. 23, 2022, the entire contents of which are incorporated herein by reference.

### BACKGROUND

The disclosure relates to a portable power supply.

Patent Literature 1 (JP H08-140349 A) discloses a portable-type power supply (hereinafter referred to as a portable power supply) including: a front panel and a rear panel opposed to each other in parallel; a middle chassis connecting the front and rear panels at a central part thereof; and a pair of side covers, one on a right side, one on a left side. The front panel, the rear panel, and the pair of side covers of the portable power supply are assembled to put the middle chassis thereamong to form a box-shaped housing. The front panel, the rear panel, and the pair of side covers are formed with resin. The portable power supply disclosed in Patent Literature 1 includes a handle formed by fitting the pair of side covers from right and left sides on the upper part of the housing. Note that the portable power supply uses a commercial power source.

Patent Literature 2 (JP H07-124995 A) discloses a method for manufacturing a housing through composite molding where an adhesive is applied on a metal plate, the adhesive is dried, and then resin is injected onto the adhesive layer. Using this method for manufacturing a housing, a housing having high strength in electronic apparatuses can be obtained.

In recent years, portable power supplies equipped with a secondary battery having a large battery capacity have been produced. The size and mass of the secondary battery have increased as the battery capacity has increased.

When a secondary battery is mounted in the conventional housing structure described in Patent Literature 1 where a commercial power source is used, it is necessary to increase the strength of the housing along with the increase in the size and mass of the mounted secondary battery. This is because there is a concern that, in the conventional housing structure, in a case where the portable power supply is repeatedly transported by gripping the upper handle, since the housing is made from resin and the pair of side covers are arranged in a divided manner on the left and right sides, if sufficient strength cannot be maintained due to deterioration of the resin over time, or the like, then the housing may become distorted, and the secondary battery may not be securely held.

Note that when the technique described in Patent Literature 2 is applied to maintain the housing with high strength, there is a concern that the number of manufacturing processes will increase, and the cost will increase.

### SUMMARY

A portable power supply according to an aspect of the present embodiment includes a secondary battery, and a housing including a lower housing that accommodates and supports the secondary battery and has a box shape with an open upper surface, and a lid housing that is arranged to cover the lower housing from above, the housing including a first handle part and a second handle part on opposing edge parts of an upper edge part thereof, so as to be portable by hand. Each of the first handle part and the second handle part includes a base part made from a metal, as a core material. The lid housing, the lower housing, and the base part of each of the first handle part and the second handle part are held through screwing of a male screw bolt and a female screw bolt which are inserted in the housing in a vertical direction of the housing.

### BRIEF DESCRIPTION OF DRAWINGS

FIG. 1A is a first perspective view of a power supply 91, which is a portable power supply according to an embodiment, as viewed obliquely upward from the right.

FIG. 1B is a second perspective view of the power supply 91 as viewed obliquely downward from the right.

FIG. 2 is a top view of the power supply 91.

FIG. 3A is a first assembly diagram of the power supply 91 as viewed obliquely upward from the right.

FIG. 3B is a second assembly diagram of the power supply 91 as viewed obliquely downward from the right.

FIG. 4A is a plan view illustrating a base part 71 of a handle unit 7.

FIG. 4B is a cross-sectional side view of part of the base part 71.

FIG. 4C is a plan view of the handle unit 7.

FIG. 4D is a side view including a cross section taken along IVD-IVD in FIG. 4C.

FIG. 5A is a cross-sectional view taken along VA-VA in FIG. 2.

FIG. 5B is a cross-sectional view taken along VB-VB in FIG. 2.

### DETAILED DESCRIPTION

A portable power supply according to an embodiment will be described with reference to a power supply 91, which is an example.

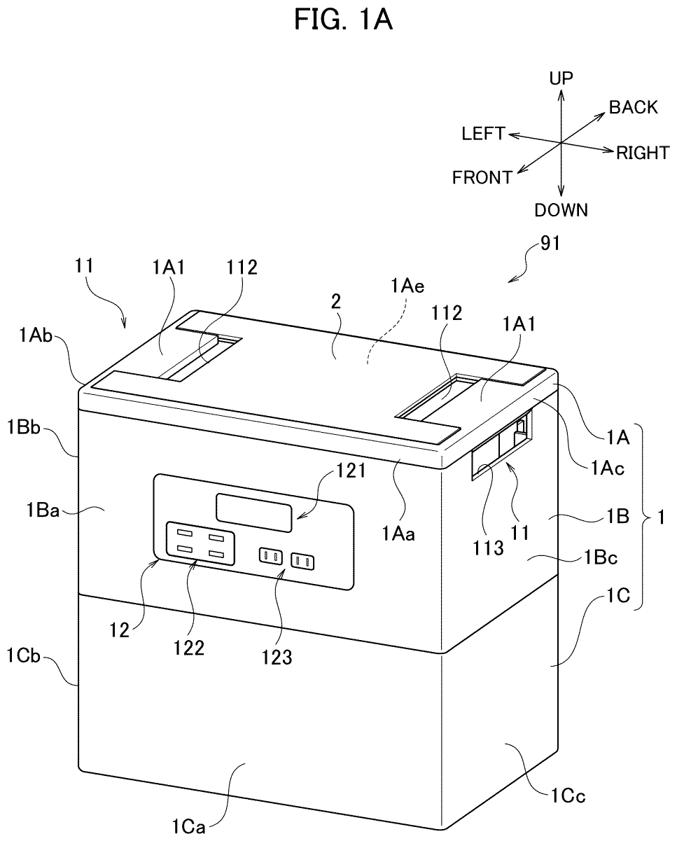

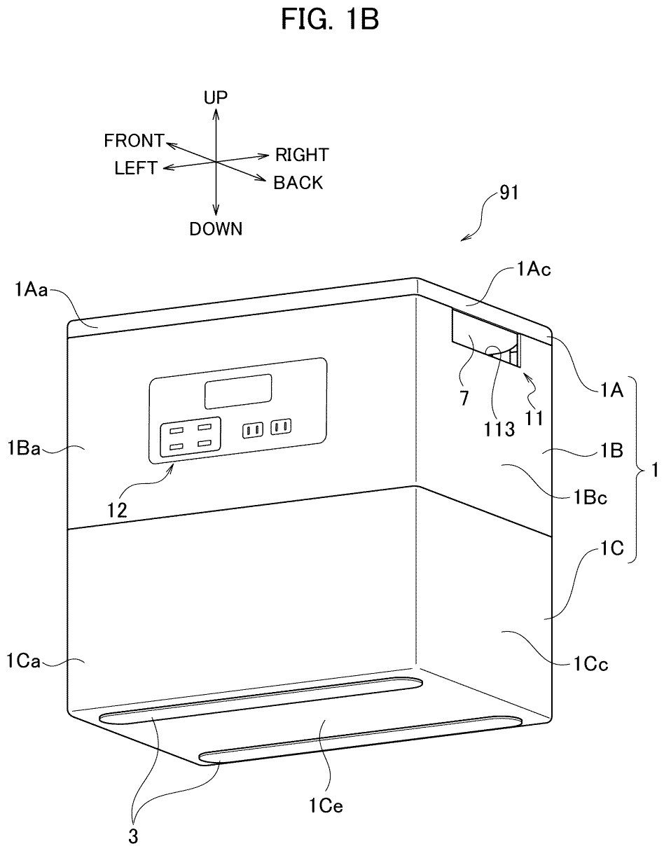

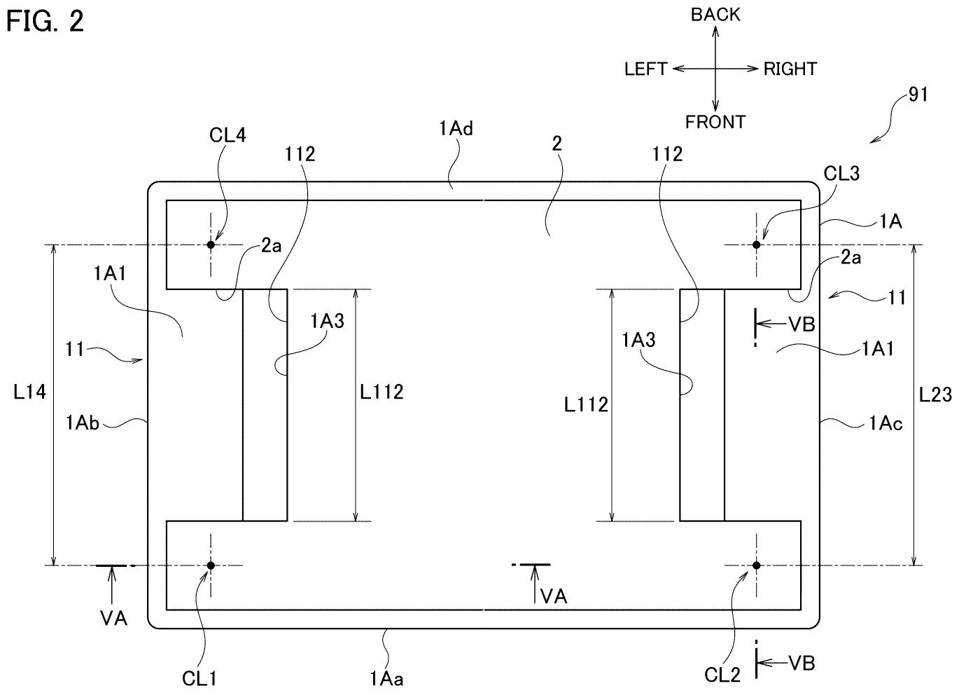

First, an external aspect of the power supply 91 will be described with reference to FIGS. 1A, 1B, and 2. FIG. 1A is a first perspective view of the power supply 91, which is the portable power supply according to the embodiment, as viewed obliquely upward from the right. FIG. 1B is a second perspective view of the power supply 91 as viewed obliquely downward from the right. FIG. 2 is a top view of the power supply 91. For convenience of explanation, front, back, left, right, up, and down directions are indicated by arrows in FIG. 1A.

The power supply 91 is a portable power supply that uses a secondary battery, such as a lithium ion secondary battery, as a power source, and can be carried by hand.

As illustrated in FIG. 1A, the power supply 91 has a box shape in appearance by means of a housing 1. The housing 1 is configured to have a box shape by combining a lid housing 1A, an upper housing 1B, and a lower housing 1C.

The housing 1 includes the lower housing 1C on the lower side, and the upper housing 1B on the upper side, with a boundary at a position approximately half of the total height. The lid housing 1A is assembled to cover the upper part of the upper housing 1B. The lid housing 1A is attached with a top plate 2 that includes a pair of cut parts 2a and is formed in an approximate H-shape.

A front surface part 1Ba of the upper housing 1B is provided with an operating part 12. The operating part 12 is provided with a display part 121, a first power source output part 122, and a second power source output part 123. The display part 121 displays an operating state or the like of the power supply 91. The first power source output part 122 and the second power source output part 123 respectively have multiple USB terminals and two-pole outlets, for example. Note that although two-pole outlets are exemplified as the second power source output part 123 in the drawing, the shape and the number of poles of the outlet are not limited to them.

Handle parts 11 are provided on opposing edge parts of an upper edge part of the housing 1. Note that one of the handle parts 11 provided on one of the opposing edge parts of the upper edge part is also referred to as a first handle part, and the other of the handle parts 11 provided on the other of the opposing edge parts of the upper edge part is also referred to as a second handle part. The handle parts 11 each include: a handle unit 7 described below; an upper opening part 112 that is formed on an upper surface of a top surface part 1A1 and is longer in the front-back direction; and a side opening part 113 that is formed on an upper side part of a left surface part 1Bb, or an upper side part of a right side part 1Bc, and is longer in the front-back direction. The upper opening part 112 and the side opening part 113 are connected to each other inside the housing 1. Fingers FG excluding the thumb can be inserted through each side opening part 113 to lift the power supply 91.

A pair of feet 3 extending in the left-right direction are attached on the lower surface of a bottom surface part 1Ce of the lower housing 1C, separated from each other in the front-back direction.

The lid housing 1A, the upper housing 1B, and the lower housing 1C are formed with a resin. An example of the resin is a polymer alloy of a polycarbonate resin and an ABS resin. The top plate 2 and the feet 3 are formed with rubber or an elastomer resin.

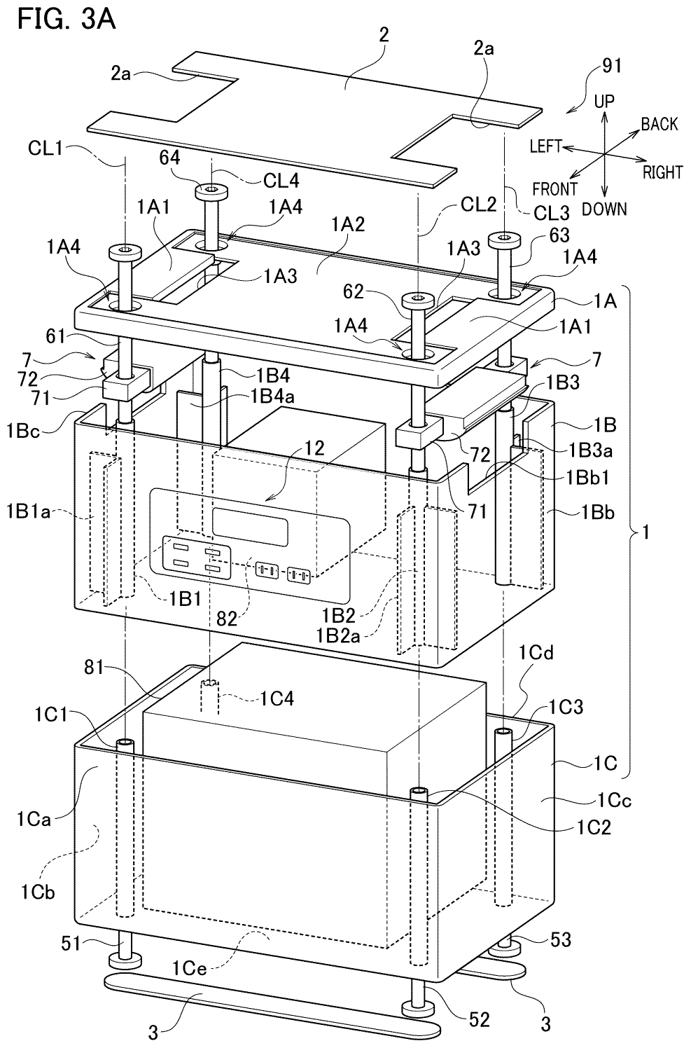

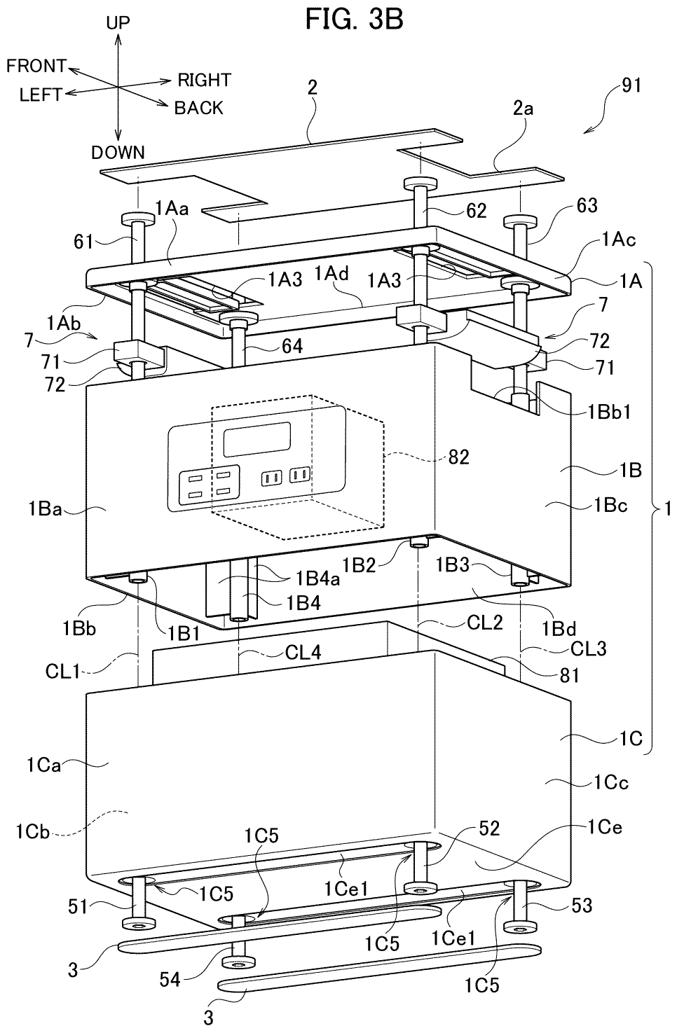

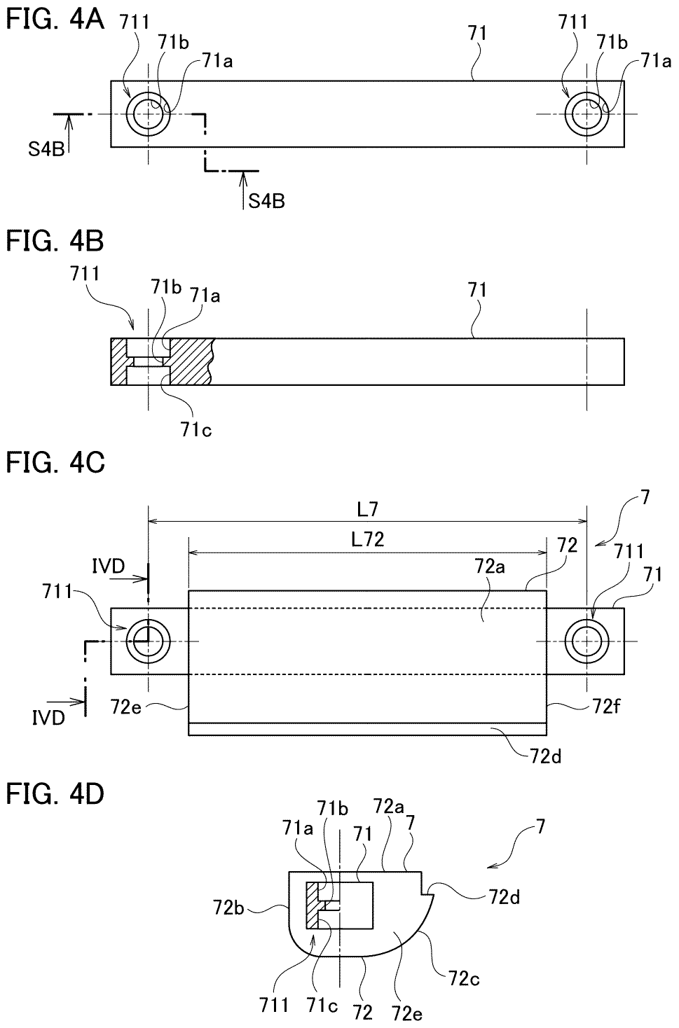

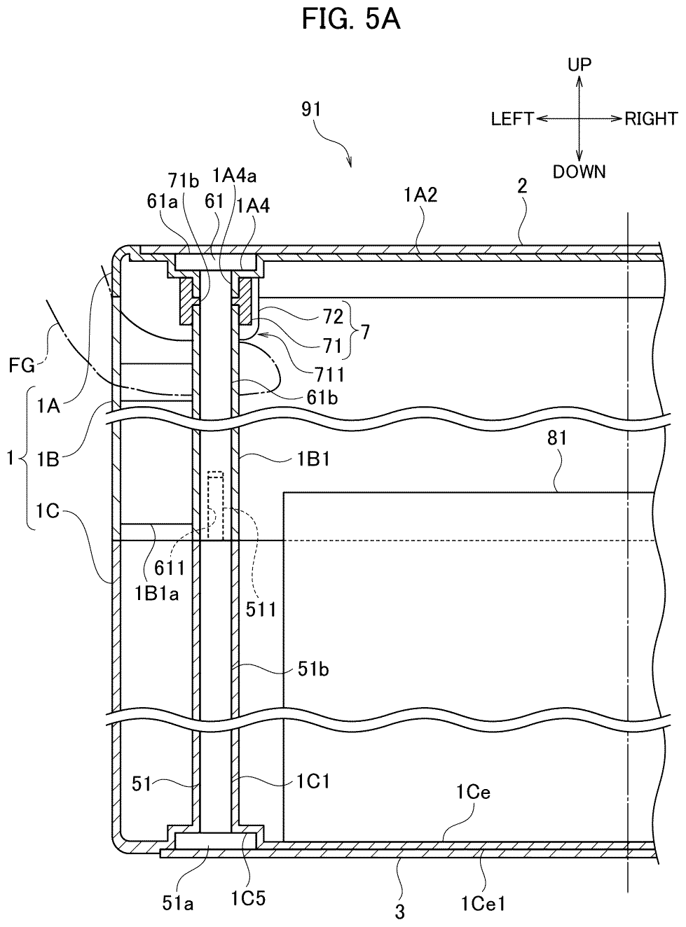

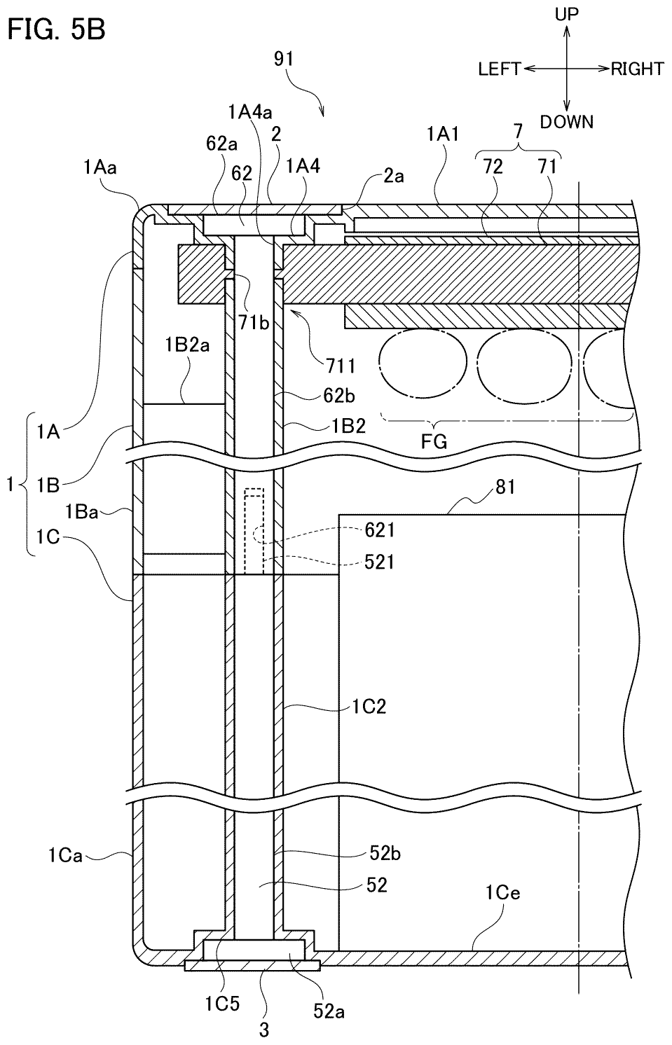

Next, a structure of the power supply 91 will be described with reference to FIGS. 3A to 5B. FIG. 3A is a first assembly diagram of the power supply 91 viewed obliquely upward from the right. FIG. 3B is a second assembly diagram of the power supply 91 viewed obliquely downward from the right. FIG. 4A is a plan view illustrating the base part 71 serving as a core material of the handle unit 7. FIG. 4B is a cross-sectional side view of part of the base part 71. FIG. 4C is a plan view of the handle unit 7. FIG. 4D is a side view including a cross section taken along IVD-IVD in FIG. 4C. FIG. 5A is a cross-sectional view taken along VA-VA in FIG. 2. FIG. 5B is a cross-sectional view taken along VB-VB in FIG. 2.

As illustrated in FIG. 3A, the lower housing 1C includes the bottom surface part 1Ce, a front surface part 1Ca, a left surface part 1Cb, a right surface part 1Cc, and a back surface part 1Cd. The bottom surface part 1Ce has a rectangular shape in a top view. The front surface part 1Ca, the left surface part 1Cb, the right surface part 1Cc, and the back surface part 1Cd respectively stand upward from four edge parts on the upper surface side of the bottom surface part 1Ce. Consequently, the lower housing 1C is formed in a box shape with the upper part open.

In the vicinity of four corners of the bottom surface part 1Ce, bosses 1C1 to 1C4 having through holes (through hole portions) passing in the up-down direction (vertical direction) are formed at positions symmetrical in the front, back, left, and right. The bosses 1C1 to 1C4 are also referred to as second bosses.

Axes CL1 to CL4 extending vertically through the bosses 1C1 to 1C4 are positioned at apexes of the rectangle in the top view, and a secondary battery 81 is fixed in the region inside the rectangle. The secondary battery 81 has a rectangular parallelepiped shape, and is fixed to the bottom surface part 1Ce using a fixing member (not illustrated).

In this example, corner parts of the secondary battery 81 in the top view are positioned in the immediate vicinity of the bosses 1C1 to 1C4. An example is illustrated where a height position of the upper surface of the secondary battery 81 is above the upper end of the lower housing 1C. However, the height position of the upper surface of the secondary battery 81 may be below the upper end of the lower housing 1C.

As described above, the secondary battery 81 is partially or entirely accommodated in the lower housing 1C having a box shape, and is fixed to the bottom surface part 1Ce.

The upper housing 1B is formed as a rectangular frame-like body having a shape corresponding to the upper end part of the lower housing 1C such that the front surface part 1Ba, the left surface part 1Bb, the right surface part 1Bc, and a back surface part 1Bd can be connected to the upper end of the lower housing 1C.

In the vicinity of four corners of the upper housing 1B, bosses 1B1 to 1B4 having through holes (through hole portions) with the axes CL1 to CL4 as axes are arranged. The bosses 1B1 to 1B4 are also referred to as first bosses. As illustrated in FIG. 3A, the bosses 1B1 to 1B4 each is connected to two adjacent parts from among the front surface part 1Ba, the left surface part 1Bb, the back surface part 1Bd, and the right surface part 1Bc through one of connecting ribs 1B1a to 1B4a extending in the up-down direction at the four corners inside the upper housing 1B.

As illustrated in FIG. 3B, on the lower surface of the bottom surface part 1Ce of the lower housing 1C, recesses (recess portions) 1Ce1 are formed by removing parts that correspond to the feet 3. The depth of the recesses 1Ce1 is about half the thickness of the feet 3. The feet 3 attached to the recesses 1Ce1 project downward from the lower surface of the bottom surface part 1Ce.

A circuit part 82 is arranged inside the upper housing 1B. The circuit part 82 is supported relative to the upper housing 1B by a support member (not illustrated). The circuit part 82 controls operation of supplying electric power stored in the secondary battery 81 to external devices connected to the first power source output part 122 and the second power source output part 123. The circuit part 82 further controls operation of charging the secondary battery 81 using an external power source.

As illustrated in FIGS. 2 and 3A, the lid housing 1A is formed in a rectangular flat plate shape. The lid housing 1A includes the top surface part 1A1, and as edges of the top surface part 1A1, a front edge part 1Aa, a left edge part 1Ab, a right edge part 1Ac, and a back edge part 1Ad. The lid housing 1A is a lid member that engages with an upper end of the upper housing 1B to cover an upper opening thereof.

The top surface part 1A1 includes a recess (recess portion) 1A2 that has an H-shape and stands upright in the left-right direction. That is, the recess 1A2 is formed in an H-shape where the width in the left-right direction of a central part in the front-back direction is shorter than those of both end parts in the front-back direction in the top view. A pair of opening parts 1A3 are formed in recessed parts of the H-shape where a width in the left-right direction of the recess 1A2 is shorter.

The recess 1A2 of the top surface part 1A1 is formed in such a manner that the top plate 2 is attachable to the recess 1A2. The top plate 2 having the approximate H-shape is attached to the recess 1A2 having the approximate H-shape with the pair of cut parts 2a positioned in the left-right direction. The recess 1A2 has parts exposed to the upper surface of the housing 1 from the pair of cut parts 2a of the top plate 2 with the top plate 2 attached thereto. The pair of opening parts 1A3 are formed in the corresponding parts of the recess 1A2. Note that in this embodiment, the pair of opening parts 1A3 are regarded as the upper opening parts 112 of the aforementioned handle parts 11.

As illustrated in FIG. 3A, stepped parts 1A4 are formed in the vicinity of four corners of the lid housing 1A. The stepped parts 1A4 are positioned in the recess 1A2, and are formed to be further recessed in from the recess 1A2. In the stepped parts 1A4, through holes 1A4a are respectively formed having the axes CL1 to CL4 positioned at corresponding corners, as axes. As an example, FIGS. 5A and 5B illustrate through holes 1A4a having the axes CL1 and CL2. As illustrated in FIG. 2, a distance L14 that is a distance in the front-back direction between the axis CL1 and the axis CL4, and a distance L23 that is a distance in the front-back direction between the axis CL2 and the axis CL3, are the same.

As illustrated in FIG. 3A, one of the handle units 7 is arranged between the pair of stepped parts 1A4 on the left edge side of the lid housing 1A, and the bosses 1B1 and 1B4 of the upper housing 1B. Similarly, the other of the handle units 7 is arranged between the pair of stepped parts 1A4 on the right edge side of the lid housing 1A, and the bosses 1B2 and 1B3 of the upper housing 1B.

As illustrated in FIGS. 4C and 4D, each of the handle units 7 is formed with a base part 71 and a grip part 72 as one body.

As illustrated in FIG. 4A, the base part 71 has a quadrangular prism shape, and a shaft insertion part 711 is formed in the vicinity of each end part. The base part 71 is formed through die casting or carving of a metal.

As illustrated in FIGS. 4A and 4B, the shaft insertion part 711 includes seat parts 71a and 71c that are recessed into a circular (cylindrical) shape from a pair of opposing surfaces of the base part 71. Further, a through hole 71b is formed in the bottom part of the shaft insertion part 711 between the seat parts 71a and 71c with an inner diameter smaller than the inner diameter of the seat parts 71a and 71c. A distance L7 that is a distance between the axes of the pair of shaft insertion parts 711 is the same as each of the aforementioned distances L14 and L23 illustrated in FIG. 2.

As illustrated in FIG. 4D, the grip part 72 has an upper surface 72a, a side surface 72b, and a lower surface 72c that form an outer shape in a side view. The upper surface 72a is parallel to one surface (the upper surface in FIG. 4D) of the base part 71. The side surface 72b is connected to one end side of the upper surface 72a in a side view, and is perpendicular to the upper surface 72a. The lower surface 72c is connected to a lower end of the side surface 72b through a curved surface, and is connected to the other end side of the upper surface 72a by curving upward in an arc shape through a region parallel to the upper surface 72a. A stepped part 72d that is recessed into an L shape is formed at a connection part between the lower surface 72c and the upper surface 72a, as illustrated in the outer shape in a side view.

The base part 71 is made from a metal, and the grip part 72 is made from an elastomer.

As illustrated in FIG. 5A, on the axis CL1, an upper bolt 61 is inserted, from the upper side, into: the through hole 1A4a of the stepped part 1A4 of the lid housing 1A; the through hole 71b of the shaft insertion part 711 of the handle unit 7; and a through hole of the boss 1B1 of the upper housing 1B.

The upper bolt 61 is a hexagon socket internal thread metal bolt, and includes a head part 61a and a body part 61b. A female screw part 611 is formed at the tip of the body part 61b as an internal thread on an axis line common to the body part 61b. The position of the tip of the body part 61b is near the boundary position between the upper housing 1B and the lower housing 1C.

In contrast, a stepped part 1C5 that is a circular (cylindrical) recess centered on the axis line CL1 is formed in the recess 1Ce1 of the lower housing 1C. A through hole of the boss 1C1 is opened in the stepped part 1C5 of the recess 1Ce1.

A lower bolt 51 is inserted upward from the lower side in the through hole of the boss 1C1 of the stepped part 1C5 of the lower housing 1C.

The lower bolt 51 is a hexagon socket stepped metal bolt, and includes a head part 51a and a body part 51b. A male screw part 511 protruding with an outer diameter smaller than that of the body part 61b is formed at the tip of the body part 61b. The male screw part 511 is screwed in the female screw part 611 of the upper bolt 61.

As illustrated in FIG. 5B, on the axis line CL2, an upper bolt 62 is inserted, from the upper side, into: the through hole 1A4a of the stepped part 1A4 of the lid housing 1A; the through hole 71b of the shaft insertion part 711 of the handle unit 7; and a through hole of the boss 1B2 of the upper housing 1B.

As with the upper bolt 61, the upper bolt 62 includes a body part 62b, and a head part 62a where a female screw part 621 is formed.

The stepped part 1C5, which is a circular (cylindrical) recess centered on the axis CL2, is formed in the recess 1Ce1 of the lower housing 1C. The through hole of the boss 1C2 is opened in the stepped part 1C5 of the recess 1Ce1.

The lower bolt 52 is inserted upward, from the lower side, in the through hole of the boss 1C2 of the stepped part 1C5 of the lower housing 1C.

As with the lower bolt 51, the lower bolt 52 includes a body part 52b where a male screw part 521 is formed, and a head part 52a. The male screw part 521 is screwed in the female screw part 621 of the upper bolt 62.

As illustrated in FIGS. 5A and 5B, the upper bolts 61 and 62, and the lower bolts 51 and 52 are tightened on the same axes CL1 and CL2, respectively, in such a manner that stepped parts thereof are brought into close contact with each other by screwing the male screw parts 511 and 521 in the female screw parts 611 and 621. Similarly, the upper bolts 63 and 64, and the lower bolts 53 and 54 are tightened on the same axes CL3 and CLA, respectively, in such a manner that stepped parts thereof are brought into close contact with each other by screwing the male screw parts in the female screw parts.

In this state, the upper surfaces of the head parts 61a and 62a of the upper bolts 61 and 62 are flush with the recess 1A2 of the lid housing 1A. The lower surfaces of the head parts 51a and 52a of the lower bolts 51 and 52 are flush with the recess 1Ce1 of the lower housing 1C. Similarly, the upper surfaces of the head parts of the upper bolts 63 and 64 are flush with the recess 1A2 of the lid housing 1A. The lower surfaces of the head parts of the lower bolts 53 and 54 are flush with the recess 1Ce1 of the lower housing 1C.

Thus, the top plate 2 can be attached to the recess 1A2 of the lid housing 1A in close contact. Further, the feet 3 can be attached to the recess 1Ce1 of the lower housing 1C in close contact. Since the upper bolt 61 and the lower bolt 51 are hidden by the top plate 2 and one of the feet 3, the appearance quality of the power supply unit 91 is improved.

As described above, the upper bolts 61 to 64, and the lower bolts 51 to 54 are tightened on the axes CL1 to CL4 at the four corners of the housing 1. Consequently, the lid housing 1A, the upper housing 1B, the lower housing 1C, and the handle unit 7 are sandwiched between the head parts of the metal upper bolts 61 to 64, and the head parts of the metal lower bolts 51 to 54, and are firmly formed in one body.

Thus, the power supply 91 can be easily transported by inserting fingers FG, excluding the thumbs of left and right hands, into the left and right side opening parts 113 of the handle parts 11 of the power supply 91, respectively, and then lifting up.

When the power supply 91 is lifted and separated from the installation surface (such as a floor), the gravitational force applied to the secondary battery 81 is applied to the bottom surface part 1Ce of the lower housing 1C.

Since the lower housing 1C is formed in a box shape as one body, rigidity can be relatively high. Thus, even if the secondary battery has a large battery capacity and a large mass, deformation of the lower housing 1C can be controlled to a negligible extent.

The gravitational force applied to the entirety of the lower housing 1C, which accommodates and supports the secondary battery 81, is applied downward to the head parts of the four lower bolts 51 to 54. The lower bolts 51 to 54 are respectively screwed in the upper bolts 61 to 64 to form a substantially single piece of metal. Thus, the gravitational force applied to the entirety of the lower housing 1C including the secondary battery 81 becomes a downward force applied to the stepped parts 1A4 of the lid housing 1A due to the head parts of the upper bolts 61 to 64. This force is transmitted to the metallic base part 71 of the handle unit 7 via the stepped parts 1A4 of the lid housing 1A.

That is, in the power supply 91, when the handle unit 7 is lifted by the fingers FG as illustrated in FIGS. 5A and 5B, the entire mass including the large mass of the secondary battery 81 is supported substantially by the metallic member.

As described above, members involved in supporting the power supply 91 are substantially bolts and rod-shaped metallic members, which can be easily and relatively inexpensively obtained. These metallic members have sufficient strength and rigidity to support the mass of the secondary battery. Further, although the stepped parts 1A4 and the like of the lid housing 1A are partially interposed, the force applied to the resin in the interposed part is a compressive force, and thus a reasonable strength can be obtained.

Further, the lower housing 1C, which accommodates and directly supports the secondary battery 81, is made from resin, but has high rigidity because it is formed in a box shape.

Thus, the power supply 91, which is a portable power supply, can firmly support the secondary battery 81 with an inexpensive housing configuration.

The example described in detail above is not limited to its configuration, and may be a modified example without departing from the gist of the present invention.

An example has been described where the lower bolts 51 to 54 and the upper bolts 61 to 64 are internal thread metal bolts. However, the material is not limited to metal as long as the strength is sufficient to support the mass of the secondary battery. For example, the material may be a resin or ceramic.

An example has been described where the lower bolts 51 to 54 are stepped bolts (male screw bolt, for example, first bolt), each of which has the male screw part 511, and the upper bolts 61 to 64 are internal thread bolts (female screw bolt, for example, second bolt), each of which has the female screw part 611. However, the lower bolts 51 to 54, which are the first bolts, may be internal thread bolts, and the upper bolts 61 to 64, which are the second bolts, may be stepped bolts.

An example has been described where the stepped part 1A4 of the lid housing 1A is interposed between the base part 71 of the handle unit 7, and the head part 61a of the upper bolt 61. However, the base part 71 and the head part 61a may be configured to be in direct contact.

A metal flat washer and a spring washer may be interposed between the head part 51a of the lower bolt 51, and the lower housing 1C.

The housing 1 may be configured in such a manner that the upper housing 1B is not provided, the lid housing 1A covers the lower housing 1C from above, and the lid housing 1A and the lower housing 1C are held through screwing of the first bolts and the second bolts.

Although an embodiment of the present invention has been described above, this embodiment is presented as an example, and is not intended to limit the scope of the invention. This novel embodiments can be embodied in various other forms, and various omissions, substitutions, and changes can be made without departing from the gist of the invention. This embodiment and variations thereof are included in the scope and gist of the invention, as well as in the invention stated in the claims and the scope of their equivalents.

What is claimed is:

1. A portable power supply comprising:
a secondary battery; and
a housing including a lower housing that accommodates and supports the secondary battery and has a box shape with an open upper surface, and a lid housing that is arranged to cover the lower housing from above, the housing including a first handle part and a second handle part on opposing edge parts of an upper edge part thereof, so as to be portable by hand, wherein
each of the first handle part and the second handle part includes a base part made from a metal, as a core material, and
the lid housing, the lower housing, and the base part of each of the first handle part and the second handle part are held through screwing of a male screw bolt and a female screw bolt which are inserted in the housing in a vertical direction of the housing.

2. The portable power supply according to claim 1, wherein
in a case where one of the male screw bolt and the female screw bolt is used as a first bolt and another of the male screw bolt and the female screw bolt is used as a second bolt, the first bolt is inserted in the lower housing from a lower side, and the second bolt is inserted in the lid housing from an upper side to be screwed with the first bolt, and
in a state where the first handle part and the second handle part are gripped and lifted, a force due to gravity of the secondary battery is transmitted to the base part of each of the first handle part and the second handle part via the first bolt and the second bolt.

3. The portable power supply according to claim 1, wherein the housing includes an upper housing having a frame shape between the lower housing and the lid housing.

4. The portable power supply according to claim 3, wherein
a top surface part of the lid housing includes a recess portion to which a top plate is attachable, and four stepped parts formed in a vicinity of four corners of the top surface part of the lid housing to be further recessed into the recess portion,
in a case where one of the male screw bolt and the female screw bolt is used as a first bolt, and another of the male screw bolt and the female screw bolt is used as a second bolt,
the upper housing includes four first bosses each of which has a through hole portion passing in the vertical direction in a vicinity of each of four corners of the upper housing, and each through which the second bolt is inserted from an upper side, and
the lower housing has four second bosses each of which has a through hole portion passing in the vertical direction in a vicinity of each of four corners of a bottom surface part of the lower housing, and each through which the first bolt is inserted from a lower side,
the first handle part is arranged between one pair of stepped parts of the four stepped parts on one of left and right edges of the lid housing, and one pair of first bosses of the four first bosses on one of left and right edges of the upper housing, and
the second handle part is arranged between another pair of stepped parts of the four stepped parts on another of the left and right edges of the lid housing, and another pair of first bosses of the four first bosses on another of left and right edges of the upper housing.

5. The portable power supply according to claim 4, wherein
each first boss included in the upper housing is connected to two adjacent parts from among a front surface part, a left surface part, a back surface part, and a right surface part of the upper housing through a connecting rib extending in the vertical direction, at each of four corners inside the upper housing.

6. The portable power supply according to claim 2, wherein the housing includes an upper housing having a frame shape between the lower housing and the lid housing.

7. The portable power supply according to claim 6, wherein
a top surface part of the lid housing includes a recess portion to which a top plate is attachable, and four stepped parts formed in a vicinity of four corners of the top surface part of the lid housing to be further recessed into the recess portion,
the upper housing includes four first bosses each of which has a through hole portion passing in the vertical direction in a vicinity of each of four corners of the upper housing, and each through which the second bolt is inserted from an upper side,
the lower housing has four second bosses each of which has a through hole portion passing in the vertical direction in a vicinity of each of four corners of a bottom surface part of the lower housing, and each through which the first bolt is inserted from a lower side,
the first handle part is arranged between one pair of stepped parts of the four stepped parts on one of left and right edges of the lid housing, and one pair of first bosses of the four first bosses on one of left and right edges of the upper housing, and
the second handle part is arranged between another pair of stepped parts of the four stepped parts on another of the left and right edges of the lid housing, and another pair of first bosses of the four first bosses on another of left and right edges of the upper housing.

8. The portable power supply according to claim 7, wherein
each first boss included in the upper housing is connected to two adjacent parts from among a front surface part, a left surface part, a back surface part, and a right surface part of the upper housing, through a connecting rib extending in the vertical direction, at each of four corners inside the upper housing.
